(19) United States
(12) Patent Application Publication
(10) Pub. No.: US 2025/0345873 A1
(43) Pub. Date: Nov. 13, 2025

(54) APPARATUS FOR REPAIRING SOLDER-BALL

(71) Applicant: SAMSUNG ELECTRONICS CO., LTD., Suwon-si (KR)

(72) Inventors: Hojoon JANG, Suwon-si (KR); Sangyeon CHO, Suwon-si (KR); Hongwan KIM, Suwon-si (KR); Duckhoon PARK, Suwon-si (KR); Seunglo LEE, Suwon-si (KR); Seungho HAN, Suwon-si (KR)

(73) Assignee: SAMSUNG ELECTRONICS CO., LTD., Suwon-si (KR)

(21) Appl. No.: 19/061,495

(22) Filed: Feb. 24, 2025

(30) Foreign Application Priority Data
May 10, 2024 (KR) 10-2024-0061679

(51) Int. Cl. B23K 1/005; B23K 1/20; B23K 3/04

(52) U.S. Cl. CPC B23K 1/0056; B23K 1/203; B23K 3/04

(57) ABSTRACT

An apparatus for repairing a solder ball, may include: a base including an upper surface on which a substrate is disposed; a cover forming an internal space together with the base; a flux receiving member disposed around the substrate disposed on the base; and a heating member configured to heat a flux received in the flux receiving member. The flux received in the flux receiving member may be vaporized and applied to a solder ball having a defective shape formed on the substrate, by an indirect application method.

### CROSS-REFERENCE TO RELATED APPLICATION(S)

This application claims benefit of priority to Korean Patent Application No. 10-2024-0061679, filed on May 10, 2024 in the Korean Intellectual Property Office, the disclosure of which is incorporated herein by reference in its entirety.

### BACKGROUND

The present disclosure relates to an apparatus for repairing a solder ball.

Currently, defective solder balls detected by Final Auto Visual Inspection (AV) include defects in appearance such as ball compression, scratches, and the like. The defective solder balls may be discarded, even in the case that the defects are merely defects in appearance.

However, products with the defects in appearance, as described above, may not have problems with product characteristics, and only the appearance of a solder ball may be defective. When a shape of the solder ball can be restored by re-soldering such a solder ball having a problem only in terms of appearance, the products with the defects in appearance, as described above, can be shipped as good quality products.

### SUMMARY

An aspect of the present disclosure is to provide an apparatus for repairing a solder ball that can repair a shape of the solder ball without discoloring a surface of the solder ball.

In addition, an aspect of the present disclosure is to provide an apparatus for repairing a solder ball that can improve manufacturing yield thereof.

According to one or more example embodiments, an apparatus for repairing a solder ball, may include: a base including an upper surface on which a substrate is disposed; a cover forming an internal space together with the base; a flux receiving member disposed around the substrate disposed on the base; and a heating member configured to heat a flux received in the flux receiving member. The flux received in the flux receiving member may be vaporized and applied to a solder ball having a defective shape formed on the substrate, by an indirect application method.

According to one or more example embodiments, an apparatus for repairing a solder ball, may include: a base including an upper surface on which a substrate is disposed; a cover forming an internal space together with the base; a flux receiving member disposed around the substrate disposed on the base; a heating member configured to heat a flux received in the flux receiving member; and a flux supply module connected to the flux receiving member and configured to supply the flux. The flux received in the flux receiving member may be heated, vaporized, flow within the internal space formed by the base and the cover by convection, and be applied to a solder ball having a defective shape formed on the substrate.

According to one or more example embodiments, a method of repairing a solder ball having a defective shape, may include: providing a substrate with a solder ball having a defective shape thereon; disposing the substrate within an enclosed space; providing flux to the enclosed space; vaporizing the flux by heating the flux, to apply the vaporized flux to the solder ball; heating the solder ball to a first temperature to remove an oxide on the solder ball; and heating the solder ball to a second temperature higher than the first temperature to re-melt melt the solder ball and correct a shape of the solder ball.

### BRIEF DESCRIPTION OF DRAWINGS

The above and other aspects, features, and advantages of the present disclosure will be more clearly understood from the following detailed description, taken in conjunction with the accompanying drawings:

FIG. 1 is a configuration diagram illustrating an apparatus for repairing a solder ball according to one or more example embodiments;

FIG. 2 is an illustrative diagram for illustrating the operation of an apparatus for repairing a solder ball according to one or more example embodiments;

FIG. 3 is an illustrative diagram for illustrating the operation of an apparatus for repairing a solder ball according to one or more example embodiments;

FIG. 4 is an illustrative diagram for illustrating the operation of an apparatus for repairing a solder ball according to one or more example embodiments;

FIG. 5 is an illustrative diagram for illustrating the operation of an apparatus for repairing a solder ball according to one or more example embodiments;

FIG. 6 is a configuration diagram illustrating an apparatus for repairing a solder ball according to one or more example embodiments; and

FIG. 7 is a configuration diagram illustrating an apparatus for repairing a solder ball according to one or more example embodiments.

### DETAILED DESCRIPTION

Hereinafter, preferred example embodiments of the present disclosure will be described with reference to the attached drawings.

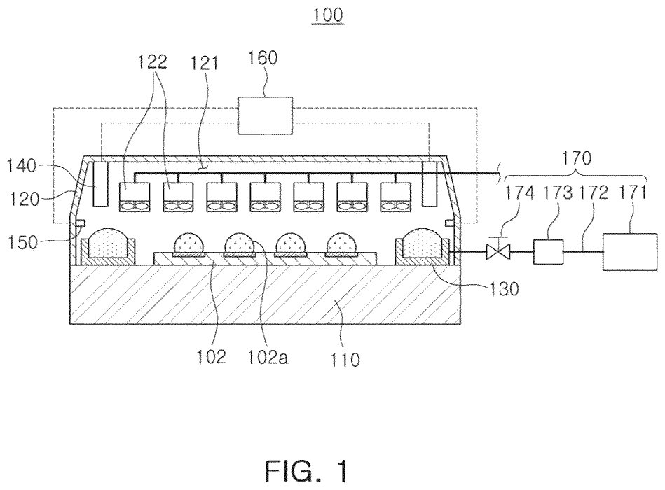

FIG. 1 is a configuration diagram illustrating an apparatus for repairing a solder ball according to one or more example embodiments.

Referring to FIG. 1, an apparatus for repairing a solder ball 100 according to one or more example embodiments may include a base 110, a cover 120, a flux receiving member 130, a heating member 140, a sensor 150, and a control unit 160 (controller).

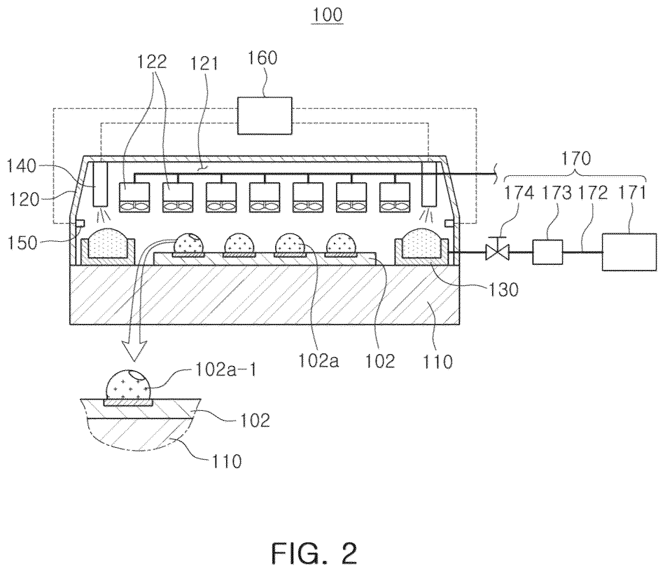

The substrate 102 may be seated or disposed on a central portion of an upper surface of the base 110. Meanwhile, the base 110 forms an internal space (enclosed space) together with the cover 120, and when the solder ball 102a formed on the substrate 102 is repaired, a space formed by the base 110 and the cover 120 forms a sealed space. Meanwhile, the substrate 102 may be provided with a plurality of solder balls 102a, and among the plurality of solder balls 102a, a solder ball 102a-1 (see FIG. 2) having a defective shape may be included. The substrate with the defective solder ball 102a-1 may thereby be provided in an enclosed space. As an example, the flux receiving member 130 may be disposed on an edge of an upper surface of the base 110. Meanwhile, a coating layer which is not removed by organic acid contained in the vaporized flux may be provided on the upper surface of the base 110. Accordingly, damage to the upper surface of the base 110 caused by vaporized flux may be prevented. However, the material of the base 110 is not limited thereto, and may be formed of a material not reacting with the organic acid contained in the vaporized flux.

The cover 120 forms an internal space together with the base 110. As an example, the cover 120 may be provided with a blowing fan 122 to form an airflow in the internal space. Meanwhile, the cover 120 may be provided with a groove 121 recessed into an upper portion thereof to form an internal space together with the base 110. Accordingly, an internal space is formed by the groove 121 formed by the upper surface of the base 110 and the cover 120. Meanwhile, an inner surface of the cover 120 may be provided with a coating layer which is not removed by organic acid contained in the vaporized flux. Accordingly, damage to the inner surface of the cover 120 caused by vaporized flux can be prevented. However, the material of the cover 120 is not limited thereto and may be formed of a material not reacting with the organic acid contained in the vaporized flux.

The flux receiving member 130 may be disposed on the upper surface of the base 110 so as to be disposed at an edge of the substrate 102. The flux receiving member 130 receives flux in a liquid or solid state. As an example, the flux receiving member 130 may have a strip shape inside which the substrate 102 may be disposed, or a plurality of flux receiving members 130 may be disposed to be spaced apart from each other along the edge of the substrate 102. Meanwhile, the flux receiving member 130 may be connected to a flux supply module 170 for supplying a flux. Accordingly, a certain amount of flux may be periodically supplied to the flux receiving member 130. As an example, the flux supply module 170 may be provided with a flux supply source 171, a connection pipe 172 connecting the flux supply source 171 and the flux receiving member 130, and a pump 173 installed on the connection pipe 172 to supply flux from the flux supply source 171 to the flux receiving member 130. In addition, the connection pipe 172 may be provided with a valve 174 to adjust an amount of flux supplied. Meanwhile, the flux received in the flux receiving member 130 may serve to remove the oxide film of the solder ball 102a-1 (see FIG. 2) having a defective shape formed on the substrate 102.

The heating member 140 serves to heat the flux received in the flux receiving member 130. For example, the heating member 140 may be installed on the cover 120 and disposed to face the flux receiving member 130. Meanwhile, the heating member 140 may radiate one of a laser or light. As an example, the heating member 140 may be comprised of a laser generator radiating an ultra-short (ps, picoseconds) pulse laser to an ultra-short (ms, millisecond) pulse laser, or a xenon lamp radiating light. However, the present disclosure is not limited to the case in which the heating member 140 is comprised of a laser generator radiating an ultra-short (ps, picoseconds) pulse laser to an ultra-short (ms, millisecond) pulse laser, and a xenon lamp, and the heating member 140 may be changed to any configuration that can provide a heating source that can vaporize the flux received in the flux receiving member 130. As described above, the flux received in the flux receiving member 130 may be heated through the heating member 140 to vaporize the flux received in the flux receiving member 130, so that the flux vaporized by convection may flow in the internal space formed by the cover 120 and the base 110. Then, the vaporized flux is applied to the solder ball 102a-1 having a defective shape formed on the substrate 102 by convection. Accordingly, the surface oxide film applied to the solder ball 102a-1 can be removed by the vaporized flux. Thereafter, the solder ball 102a-1 can be restored to a normal shape thereof.

The sensor 150 may be installed on the base 110 or the cover 120 to be disposed in the internal space formed by the base 110 and the cover 120. As an example, the sensor 150 may serve to measure a flow rate of vaporized flux. Meanwhile, the sensor 150 may be a sensor measuring a flow rate of gas in an internal space or a concentration of flux. As an example, the sensor 150 may be comprised of at least one of a first sensor measuring the flow rate and a second sensor measuring the concentration of the flux. However, the sensor 150 is not limited thereto and may be changed to any sensor that can detect the amount of vaporized flux. Meanwhile, the sensor 150 is connected to a control unit 160 and transmits information about the flow rate or concentration of the flux detected by the sensor 150 to the control unit 160.

The control unit 160 may be connected to the sensor 150 and the heating member 140. As an example, the control unit 180 controls the heat applied by the heating member 140 through information on the flow rate or concentration of the flux transmitted from the sensor 150 to adjust an amount of vaporization of the flux received in the flux receiving member 130. Thereby, the control unit 160 adjusts the concentration of flux convecting in the internal space of the base 110 and the cover 120. Meanwhile, the control unit 180 is connected to the flux supply module 170 and may also serve to adjust a supply amount of flux supplied to the flux receiving member 130.

As described above, the shape of the defective solder ball 102a-1 formed on the substrate 102 may be restored (corrected) through convection of the flux heated and vaporized through the heating member 140. Thus, the vaporized flux is applied to the defective solder ball 102a-1. As described above, by performing restoration of the solder ball 102a-1 having a defective shape formed on the substrate 102 by an indirect application method, a direct flux application process and a cleaning process of the applied flux can be avoided.

Therefore, it is possible to repair the shape of the solder ball 102a-1 without discoloring the surface of the solder ball 102a-1, and the direct flux application process and the cleaning process of the applied flux may be omitted, thereby improving manufacturing yield.

Hereinafter, the operation of an apparatus for repairing a solder ball according to one or more example embodiments will be described with reference to the drawings.

FIGS. 2 to 4 are illustrative diagrams for illustrating the operation of an apparatus for repairing a solder ball according to one or more example embodiments.

First, referring to FIG. 2, a substrate 102 is disposed or seated on the base 110 of the apparatus for repairing a solder ball 100. Meanwhile, at least a portion of the solder balls 102a formed on the substrate 102 may be solder balls 102a-1 with defects in appearance.

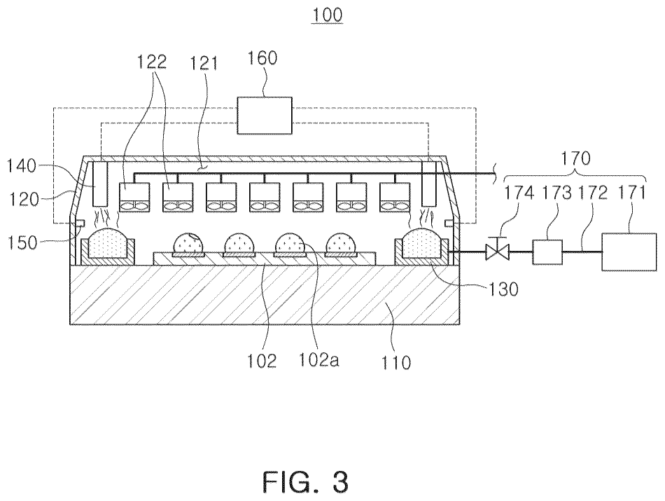

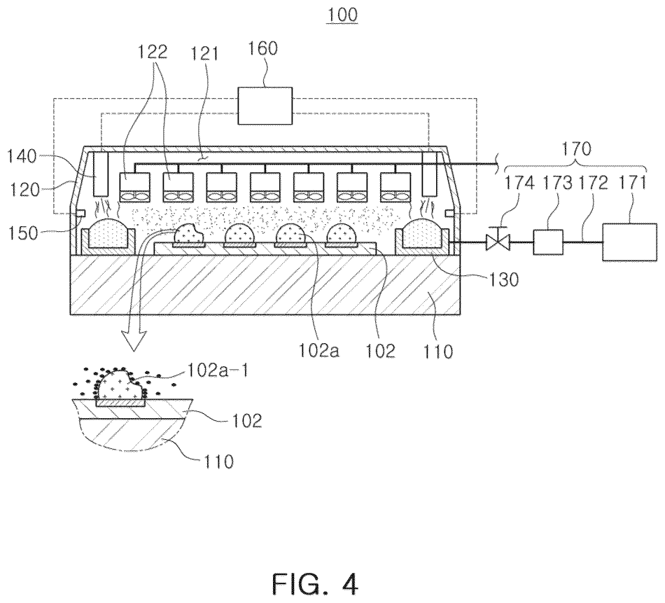

In this case, the control unit 160 heats the flux received in the flux receiving member 130 through the heating member 140, as shown in FIG. 3. Accordingly, as shown in FIG. 4, the flux is vaporized, and the vaporized flux flows in the internal space formed by the base 110 and the cover 120 by convection.

Thereafter, as shown in FIG. 4, organic acid contained in the vaporized flux removes an oxide film (SnO) formed on the solder ball 102a-1 with defects in appearance. In this case, a temperature of the internal space and/or the defective solder ball 102a-1 may be approximately 140° C. to 160° C. (first temperature).

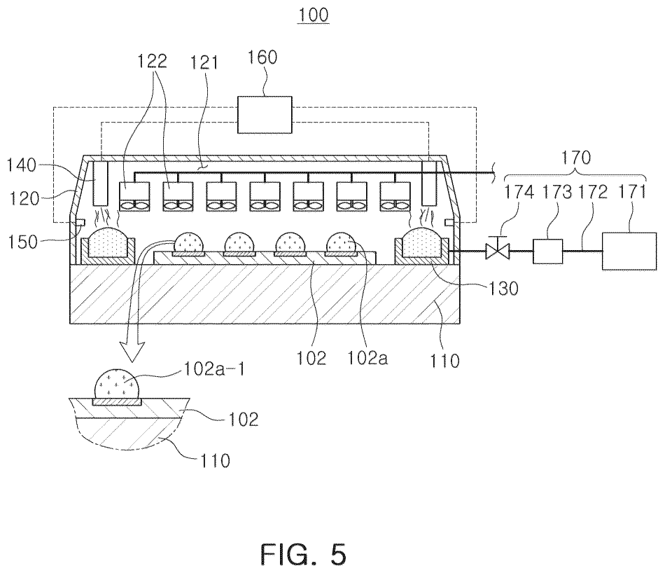

Thereafter, when a temperature of the solder ball 102a-1 in which defects in appearance are formed by the heating member 140 is further increased, the solder ball 102a-1 may be re-melted, and as shown in FIG. 5, the shape of the solder ball 102a-1 may be restored. Meanwhile, the temperature at which the solder ball 102a-1 is re-melted may be approximately 218° C. or higher (second temperature).

As described above, the shape of the defective solder ball 102a-1 formed on the substrate 102 may be restored through convection of the flux heated and vaporized through the heating member 140. As described above, by performing restoration of the defective solder ball 102a-1 formed on the substrate 102 by an indirect application method, there is no need to perform a direct flux application process and a cleaning process of the applied flux.

Therefore, it is possible to repair the shape of the solder ball 102a-1 without discoloring the surface of the solder ball 102a-1, and the direct flux application process and the cleaning process of the applied flux may be omitted, thereby improving manufacturing yield.

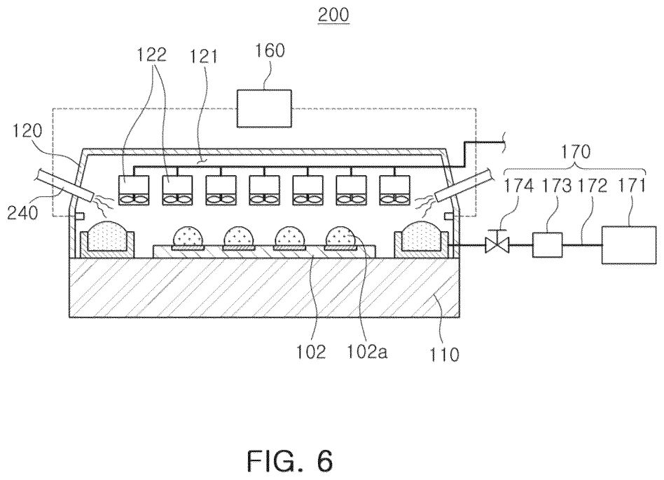

FIG. 6 is a configuration diagram illustrating an apparatus for repairing a solder ball according to one or more example embodiments.

Referring to FIG. 6, an apparatus for repairing a solder ball 200 according to one or more example embodiments includes a base 110, a cover 120, a flux receiving member 130, a heating member 240, a sensor 150, and a control unit 160.

Meanwhile, since the base 110, the cover 120, the flux receiving member 130, the sensor 150, and the control unit 160 are substantially the same as the components described in the above-described embodiment, detailed description will be omitted here and the above description will be replaced.

The heating member 240 serves to heat flux received in the flux receiving member 130. Meanwhile, the heating member 240 may be installed on one of the base 110 or the cover 120. As an example, the heating member 240 provides heat to the flux received in the flux receiving member 130 by convection. Meanwhile, the heating member 240 supplies convective heat by high-temperature air. For example, the heating member 240 serves to supply high temperature air to an internal space formed by the base 110 and the cover 120. High-temperature air supplied to the internal space formed by the base 110 and the cover 120 by the heating member 240 flows in the internal space formed by the base 110 and the cover 120 by convection. Accordingly, the flux received in the flux receiving member 130 is heated. Accordingly, the flux received in the flux receiving member 130 may be vaporized and the flux vaporized by convection may flow in the internal space formed by the cover 120 and the base 110. The vaporized flux may restore a shape of a solder ball 102a-1 having a defective shape formed on the substrate 102 by convection. As an example, the solder ball 102a-1 having a defective shape formed on the substrate 102 may have the shape restored after a surface oxide film is removed by the vaporized flux.

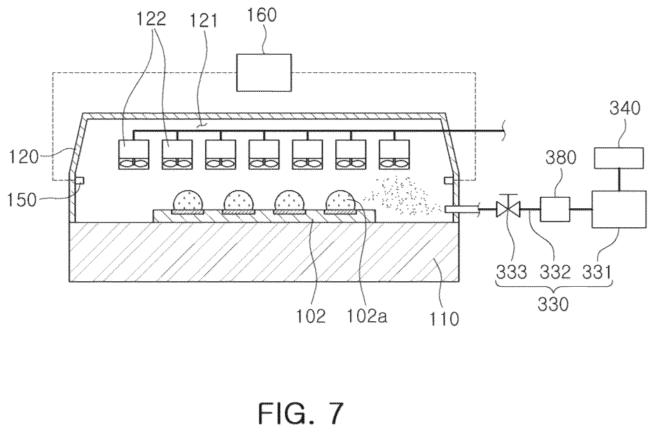

FIG. 7 is a configuration diagram illustrating an apparatus for repairing a solder ball according to one or more example embodiments.

Referring to FIG. 7, an apparatus for repairing a solder ball 300 according to one or more example embodiments includes a base 110, a cover 120, a flux supply module 330, a heating member 340, a sensor 150, a control unit 160, and a fan motor 380.

Meanwhile, since the base 110, the cover 120, the sensor 150, and the control unit 160 are substantially the same as the components described in the above-described embodiment, detailed description will be omitted here and the above description will be replaced.

The flux supply module 330 serves to supply vaporized flux to an internal space formed by the base 110 and the cover 120. To this end, the flux supply module 330 may be installed on one of the base 110 or the cover 120. As an example, the flux supply module 330 may be provided with a heating member 340 to vaporize flux from the outside and then supply the vaporized flux to the internal space formed by the base 110 and the cover 120. The heating member 340 may be formed of a laser generator radiating an ultra-short pulse laser to radiate one of a laser or light, or a xenon lamp radiating light. The flux supply module 330 may include a flux supply source 331, the flux supply source 331 may be connected to the internal space formed by the base 110 and the cover 120 through a flux supply line 332, and a valve 333 that can adjust a supply amount of the vaporized flux may be installed in the flux supply line 332. In addition, a fan motor 380 for flowing the vaporized flux may be connected to the flux supply module 330.

As set forth above, according to the present disclosure, an apparatus for repairing a solder ball that can repair a shape of a solder ball without discoloring a surface of the solder ball may be provided.

In addition, an apparatus for repairing a solder ball that can improve manufacturing yield thereof may be provided.

The various and advantageous advantages and effects of the present disclosure are not limited to the above description, and may be more easily understood in the course of describing the specific embodiments of the present disclosure.

While example embodiments have been shown and described above, it will be apparent to those skilled in the art that modifications and variations could be made without departing from the scope of the present disclosure as defined by the appended claims.

What is claimed is:

1. An apparatus for repairing a solder ball, comprising:
a base comprising an upper surface on which a substrate is disposed;
a cover forming an internal space together with the base;
a flux receiving member disposed around the substrate disposed on the base; and
a heating member configured to heat a flux received in the flux receiving member,
wherein the flux received in the flux receiving member is vaporized and applied to a solder ball having a defective shape formed on the substrate, by an indirect application method.

2. The apparatus for repairing the solder ball of claim 1, wherein the solder ball having the defective shape formed on the substrate has a shape thereof corrected by re-melting after a surface oxide film is removed by the vaporized flux.

3. The apparatus for repairing the solder ball of claim 1, wherein a flux supply module configured to supply the flux is connected to the flux receiving member.

4. The apparatus for repairing the solder ball of claim 1, wherein the heating member is configured to radiate one of a laser or light.

5. The apparatus for repairing the solder ball of claim 4, wherein the heating member is a laser generator configured to radiate an ultra-short picoseconds pulse laser to an ultra-short millisecond pulse laser.

6. The apparatus for repairing the solder ball of claim 4, wherein the heating member is a lamp configured to radiate light.

7. The apparatus for repairing the solder ball of claim 6, wherein the lamp is a xenon lamp.

8. The apparatus for repairing the solder ball of claim 1, wherein the heating member is configured to provide heat by convection.

9. The apparatus for repairing the solder ball of claim 8, wherein the heating member is configured to provide convection heat by high-temperature air.

10. The apparatus for repairing the solder ball of claim 1, wherein the internal space further comprises a sensor configured to measure a flow rate of the vaporized flux.

11. The apparatus for repairing the solder ball of claim 10, wherein the sensor is configured to measure a flow rate of gas or a concentration of gas in the internal space.

12. The apparatus for repairing the solder ball of claim 10, further comprising:
a controller operatively coupled to the sensor and the heating member,
wherein the control unit is configured to adjust a concentration of the flux by controlling heat applied by the heating member.

13. An apparatus for repairing a solder ball, comprising:
a base comprising an upper surface on which a substrate is disposed;
a cover forming an internal space together with the base;
a flux receiving member disposed around the substrate disposed on the base;
a heating member configured to heat a flux received in the flux receiving member; and
a flux supply module connected to the flux receiving member and configured to supply the flux,
wherein the flux received in the flux receiving member is heated, vaporized, flows within the internal space formed by the base and the cover by convection, and is applied to a solder ball having a defective shape formed on the substrate.

14. The apparatus for repairing the solder ball of claim 13, wherein the heating member is configured to radiate one of a laser or light.

15. The apparatus for repairing the solder ball of claim 14, wherein the heating member is a laser generator configured to radiate an ultra-short picoseconds pulse laser to an ultra-short millisecond pulse laser, or a xenon lamp configured to radiate light.

16. The apparatus for repairing the solder ball of claim 13, wherein the heating member is configured to supply convection heat by high-temperature air.

17. The apparatus for repairing the solder ball of claim 13, wherein the internal space further comprises a sensor configured to measure a flow rate of the vaporized flux.

18. The apparatus for repairing the solder ball of claim 17, further comprising:
a controller operatively coupled to the sensor and the heating member,
wherein the control unit is configured to adjust a concentration of the vaporized flux by controlling heat applied by the heating member.

19. The apparatus for repairing the solder ball of claim 14,
wherein the flux applied to the solder ball having the defective shape removes an oxide film formed on a surface of the solder ball, and
wherein the solder ball having the defective shape has a shape thereof corrected by re-melting.

20. A method of repairing a solder ball having a defective shape, the method comprising:
providing a substrate with a solder ball having a defective shape thereon;
disposing the substrate within an enclosed space;
providing flux to the enclosed space;
vaporizing the flux by heating the flux, to apply the vaporized flux to the solder ball;
heating the solder ball to a first temperature to remove an oxide on the solder ball; and
heating the solder ball to a second temperature higher than the first temperature to re-melt the solder ball and correct a shape of the solder ball.
